(19) United States
(12) Patent Application Publication
(10) Pub. No.: US 2006/0195758 A1
(43) Pub. Date: Aug. 31, 2006

(54) Method of storing information on an optical disc

(75) Inventors: Martinus Wilhelmus Blum, Eindhoven (NL); Constant Paul Marie Jozef Baggen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 10/549,563

(22) PCT Filed: Mar. 17, 2004
(86) PCT No.: PCT/IB04/50272

§ 371 Date: Sep. 19, 2005

(30) Foreign Application Priority Data
Mar. 20, 2003 (EP) 03075834.6

(51) Int. Cl. H03M 13/00

(52) U.S. Cl. 714/758

(57) ABSTRACT

A method is described for writing information to a record medium (2). 152 code words [11(j)] each having 248 bytes [mI(ij)] and 12 BIS words each having 62 BIS bytes [b2(r,s)] are combined to form an ECC block (M3) having 38 440 elements [m3(v,w)], which elements are consecutively written. Also, a method is described for reading information from a record medium (2). An ECC block (M3) having 38 440 elements [m3(v,w)] is read, from which 152 code words [11(j)] each having 248 bytes [ml(ij)]and 12 BIS words each having 62 BIS bytes [b2(r,s)] are reconstructed.

### FIELD OF THE INVENTION

The present invention relates in general to a method of storing information on an optical disc. More specifically, the present invention relates to a storage method where information is stored in the form of ECC blocks. Also, the present invention relates to a method of reading information from such disc.

Further, the present invention relates to a disc drive apparatus for writing/reading information into/from an optical storage disc; hereinafter, such a disc drive apparatus will also be indicated as “optical disc drive”.

### BACKGROUND OF THE INVENTION

As is commonly known, an optical storage disc comprises at least one track, either in the form of a continuous spiral or in the form of multiple concentric circles, of storage space where information may be stored in the form of a data pattern. Optical discs may be of the read-only type, where information is recorded during manufacture, which information can only be read by a user. The optical storage disc may also be of a writable type, where information may be stored by a user. Such disc can be of a write-once type, which can only be written once, or of a rewritable type, which can be written many times. The present invention relates, in principle, to all types of discs, but will be explained specifically, by way of example; with respect to rewritable discs, although this example should not be considered as limiting the scope of the invention to this field. Since the technology of optical discs in general, the way in which information can be stored in an optical disc, and the way in which optical data can be read from an optical disc, is commonly known, it is not necessary here to describe this technology in more detail.

When storing information on a record medium, the information is coded in data words in accordance with a predetermined format. For different applications, different formats exist. One general problem is that, on writing and/or on reading, errors may occur, so that the data read back from a recording is not identical to the original data This is undesirable. Therefore, error-correction schemes have been developed, capable of correcting data errors to a certain extent. Such error-correction schemes involve the addition of error correction bits to the original data. In a particular class of error-correction schemes, a predefined amount of original data and error-correction bits are mixed together, according to a predefined algorithm. The combination forms an Error Correction Code block (ECC block).

Since coding schemes for ECC blocks are known to those skilled in the art, while furthermore the present invention is not related to the coding scheme as such, a detailed discussion of a coding algorithm will be omitted here. By way of example, reference is made to the DVD standard ECMA 267: “120 mm DVD - Read Only Disc”, December 1997, Section 4 “Data Format”. Also, reference is made to U.S. Pat. Nos. 6.367.049 and 6.378.100 to Van Dijk et al, who describe a method for encoding multiword information.

Basically, an ECC block comprises a predetermined number of code words, each code word having a predetermined length, i.e. comprising a predetermined number of data bytes and a predetermined number of error correction bytes. Thus, the ECC block can be considered as a collection of code words. When the ECC block is written to a storage medium, the individual bytes of the code words of one ECC block are written in a predetermined order, such that bytes of one code word are physically located at relatively large distances from each other. On reading from the storage medium, code words can only be decoded if the full code word is reconstructed by putting all bytes of this code word in the right order. The distribution of the individual bytes on the storage medium is such that, even if it is desired to decode one code word only, the entire ECC block must be read.

It is to be appreciated that the robustness of the ECC coding depends on the ratio of the number of error correction bytes to the number of data bytes: the more error correction bytes a code word comprises, the more errors can be corrected, but the trade-off is that the data capacity of the code word is reduced. In any event, if the number of error correction bytes is fixed, the maximum number of errors that can be corrected in one code word is also fixed. If the actual number of errors in one code word exceeds said maximum, the code word as a whole cannot be decoded without error. This will be indicated as the error sensitivity of an ECC block: the lower the sensitivity, the more errors are correctable.

There is a trend towards reducing physical dimensions of data storage equipment. Recently a disc drive for small discs (SFFO) was developed, suitable for implementation in mobile equipment such as a mobile telephone, Personal Digital Assistant (PDA), etc. The standard for SFFO is still under development. When developing a new standard, it is advantageous if such a new standard can be based as much as possible on an existing standard, because encoders and decoders for use in the new standard may then be based on the encoder and decoder technology already developed for the existing standard. One potentially suitable standard to be used as a basis for the SFFO standard is Blu-Ray Disc (indicated hereinafter as BRD), and the present invention has been devised against the background of the BRD standard.

In the BRD standard, an ECC block has a size of 64 kBytes (data bytes). When written on disc, such a block occupies approximately 71 mm of track length. The smallest track, i.e. the inner track, in BRD has a radius of 24 mm, hence a length of about 150 mm, which is longer than the track length occupied by one 64-kByte ECC block.

An SFFO disc has an inner track radius of about 6 mm, hence the length of the inner track is about 38 mm, which is smaller than the track length occupied by one 64-kByte ECC block. In other words, if the existing BRD standard were used in this case, the ECC blocks would occupy about two adjacent 360° track portions in the inner regions of the SFFO disc.

Such a situation would increase the error sensitivity of an ECC block, at least in respect of certain types of errors.

A first example is a burst error, i.e. relatively large errors which are usually associated with mechanical irregularities of the disc, such as a particle of dirt, a fingerprint, a scratch, etc. Such mechanical irregularities typically have a physical size larger than the distance between two adjacent tracks, such that it is practically certain that a burst error will affect two or more adjacent tracks. In a case where an ECC block would extend over two adjacent tracks, one burst error would cause two errors within the same ECC block: the part of the ECC block damaged by one burst error is now twice as large.

A second example is a random error, i.e. errors which are quite small but nevertheless large enough as to possibly affect two neighbouring tracks. Now, in a case where an ECC block extends over two adjacent tracks, it may happen that, at a certain radius, two bytes of one and the same code word are aligned, i.e. located next to each other in adjacent tracks. In such a case, a random error, small as it is, may nevertheless affect such two bytes of one word, i.e. cause two errors in one word. Furthermore, the standard interleaving procedure of BRD is such that, if two bytes of one code word align, it is highly likely that the same applies to more pairs of bytes of the same code word, while furthermore it is highly likely that the same applies to more code words of the same ECC block.

The main objective of the present invention is to overcome said problems, or at least to reduce the error sensitivity of ECC blocks.

### SUMMARY OF THE INVENTION

In order to alleviate at least some of said problems associated with reducing the radius of record tracks of record discs, the present invention proposes to use ECC blocks having a size of 32 kB. Compared with 64-kB ECC blocks, the physical length of a track occupied by such an ECC block is reduced by a factor 2, resulting in a length of about 36 mm, i.e. less than one 360° track portion.

It is noted that, when the size of an ECC block is reduced by a factor 2 , the maximum size of a burst error that can be corrected is also reduced by a factor 2 . However, with respect to random errors, the correction capacity for 32-kB blocks is the same as for 64-kB blocks. Therefore, even if a random error were to cause two errors in two consecutive 32-kB blocks, these two errors would always occur in two different code words, i.e. such a random error will now only cause one error per code word. Thus, basically, the sensitivity of each 32-kB block to a random error is the same as the sensitivity of a 64-kB block to such a random error.

It is, of course, possible to develop a new standard on the basis of 32-kB ECC blocks. However, this is not preferred: it is preferred to maintain the BRD standard as much as possible. To meet this aim, the present invention proposes a method of calculating 32-kB ECC blocks using the BRD standard for 64-kB ECC blocks as a starting point.

### BRIEF DESCRIPTION OF THE DRAWINGS

These and other aspects, features, and advantages of the present invention will be further explained by the following description of a preferred embodiment of the present invention with reference to the drawings, in which same reference numerals indicate same or similar parts, and in which:

FIG. 1 schematically shows relevant components of an optical disc drive;

FIG. 2 illustrates a digital data stream;

FIG. 3 illustrates a code word of 248 bytes;

FIG. 4 illustrates a primary matrix;

FIG. 5 illustrates a secondary matrix;

FIG. 6 schematically illustrates the secondary matrix after a row shift;

FIG. 7 schematically illustrates the matrix after insertion of BIS-columns;

FIG. 8 schematically illustrates the writing of block segments;

FIG. 9 schematically illustrates the effect of a random error;

FIG. 10 schematically illustrates a secondary matrix according to the invention;

FIG. 11 schematically illustrates this matrix after a cyclic row shift operation;

FIG. 12 schematically illustrates this matrix after insertion of BIS columns;

FIG. 13 schematically illustrates the writing of bytes as block segments;

FIG. 14 schematically illustrates the effect of a random error; and

FIG. 15 schematically illustrates an embodiment of a process of calculating a 155×248 matrix.

### DESCRIPTION OF THE INVENTION

In the following, the notation z(x)=MOD(x,y) will be used to indicate a function of x resulting in a value z in the range 0≦z≦(y-1) by subtracting n*y from x if x>0 or adding n*y to x if x<0, n being an integer.

Further, the notation z=DIV(x,y) will be used to indicate the division function where x is divided by y (i.e. x/y), the result to be rounded down to the nearest integer.

FIG. 1 schematically shows relevant components of an optical disc drive 1 capable of storing information on an optical disc 2. The disc drive 1 comprises a processing circuit 4 which, at an input 3, receives information to be stored from an arbitrary source (not shown).

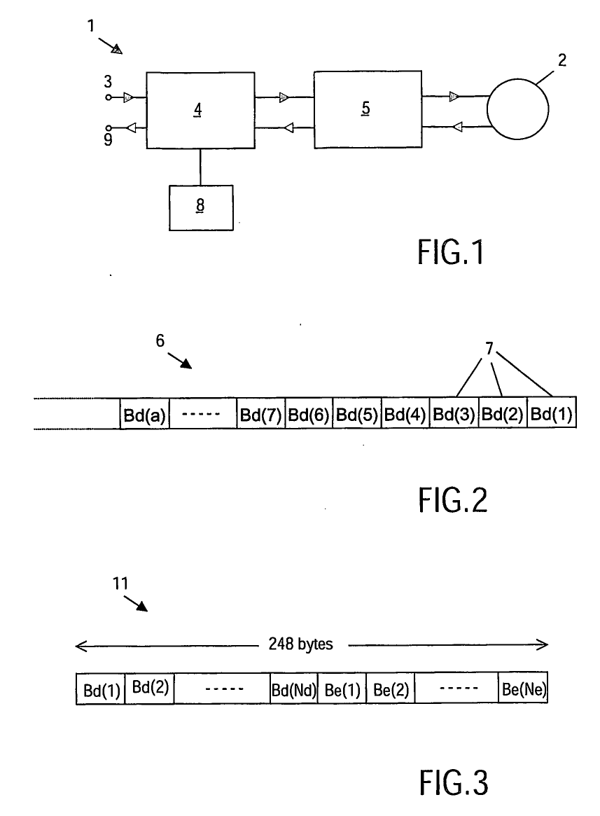

FIG. 2 illustrates the information received as a digital data stream 6, visualized as a “train” of bytes 7, which will also be indicated hereinafter as data bytes Bd(α), α being an integer used as an index. It is assumed that the “train” travels from left to right, and that the data bytes arrive at the processing circuit 4 in the order Bd(1), Bd(2), Bd(3), etc, as indicated from the right to the left in FIG. 2.

The processing circuit 4 provides bytes to be written to reading/writing means 5, which perform the actual writing on disc 2. The reading/writing means 5 comprise rotating means for rotating the disc 2, laser means for generating an optical write beam, etc, as will be clear to those skilled in the art. Since such reading/writing means are known per se, it is not necessary here to describe such reading/writing means in more detail. However, it is noted that the order in which the bytes are written on disc is not the same as the order of the bytes as received by the processing circuit 4.

In the following, the order of byte writing will be explained, first according to the existing BRD standard, later according to the method proposed by the present invention. This explanation will be illustrated with matrices, while bytes will be shown as occupying locations in such a matrix. Such illustration is clarifying in the sense that it is possible to implement an information-writing process by actually using matrix memories, indeed. However, it is to be understood that the matrices are used here merely as a tool for explanation, not necessarily as a tool for implementation. In the end, the only thing that matters is the byte writing order, and the knowledge of which bytes belong to which code word. Those skilled in the art are capable of designing a processing circuit such that it writes bytes in the desired order.

First, the processing circuit 4 performs a code word constructing step.

From the data bytes Bd received at input 3, the processing circuit 4 first constructs code words 11 in accordance with a predetermined error correction code. Although other error correction codes are possible, a generally used and well-known error correction code is the Reed Solomon code, and in the following it will be assumed that code words are in accordance with this Reed Solomon code. The processing circuit 4 receives a number Nd of data bytes (Nd being less than 248), and calculates a number Ne of error correction bytes (Ne being 248 minus Nd). Together, these Nd data bytes and the corresponding Ne error correction bytes form one code word 11 having a length of 248 bytes, as illustrated in FIG. 3. For the following explanation, the exact values of Nd and Ne are not important. It is sufficient to mention that, if all Nd data bytes and all Ne error correction bytes of a code word are available, it is possible to detect and correct some errors in this code word; generally speaking, the more error correction bytes are added, the more bytes can be corrected.

An ECC block is defined from all bytes of a group of 304 of such code words 11, without containing any byte of another code word. Thus, an ECC block comprises 304×248=75 392 bytes.

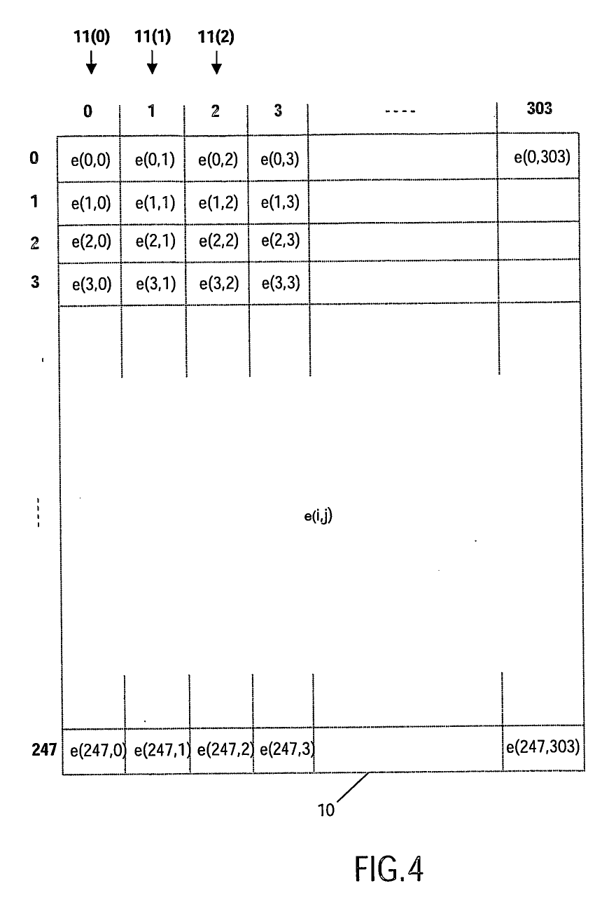

In FIG. 4, an ECC block is visualized as a matrix 10, wherein the 304 code words 11 are shown as colums 0, 1, 2, . . . 303, and wherein the bytes of these code words 11 are shown as 248 rows 0, 1, 2, . . . 247. Since each row in this matrix 10 contains exactly one code word, this matrix will hereinafter be indicated as primary matrix.

The 75 392 elements of this primary matrix 10 are indicated hereinafter as elements e(ij), wherein i indicates a row number and j indicates a column number. With reference to FIG. 2, elements e(i=0-(Nd-1),0) correspond to data bytes Bd(α=1-Nd) of the first code word 11(0), elements e(i=0-(Nd-1),1) correspond to data bytes Bd(α=(Nd+1)-2Nd) of the second code word 11(1), etc. Elements e(i=Nd-247,0) correspond to error correction bytes, which will be indicated as Be(β=1-Ne), β being an integer used as an index.

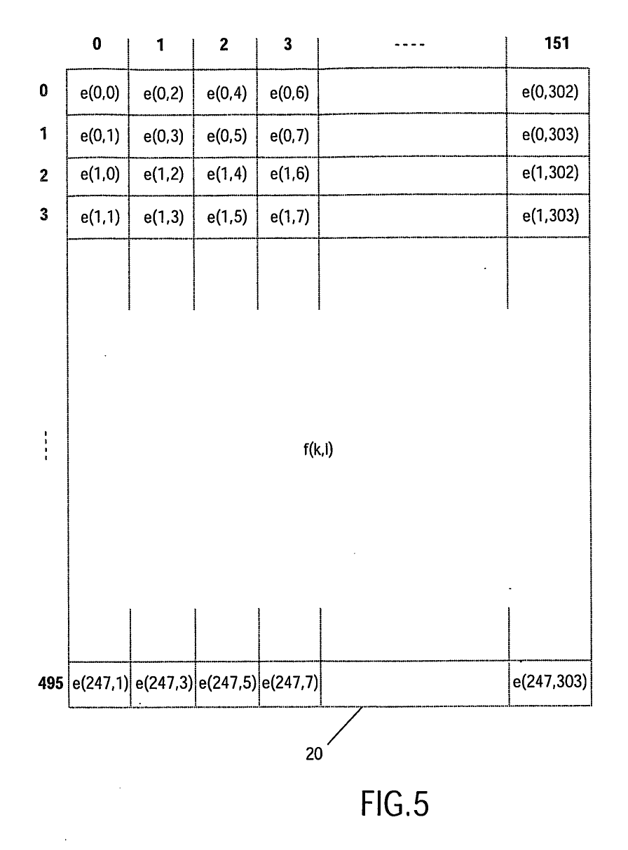

From this primary matrix 10, a secondary matrix 20 having 152 columns of 496 bytes is constructed, each column comprising the bytes of two code words. This secondary matrix 20 is illustrated in FIG. 5. The elements of this secondary matrix 20 will be indicated as f(k,l), wherein k indicates a row number and 1 indicates a column number. For each 1 between 0 and 151, column 1 is filled by the bytes of code words 11(21) and 11(21+1), i.e. elements e(i=0-247,21) and e(i=0-247,21+1) of the primary matrix 10. Elements e(i,21) of the primary matrix 10 are placed at location f(2i,1) of the secondary matrix 20, while elements e(i,21+1) of the primary matrix 10 are placed at location f(2i+1,1) of the secondary matrix 20. Thus, the elements e(i,j) of the original 304×248 ECC block matrix 10 are displaced to elements f(k,l) of the 152×496 matrix 20, according to the following relationships:
k=2i for j=0, 2, 4, 6, 8, . . . 302 (1a)
l=j/2 for j=0, 2, 4, 6, 8, . . . 302 (1b)
k=2i+1 for j=1, 3, 5, 7, 9, . . . 303 (1c)
l=(j-1)/2 for j=1, 3, 5, 7, 9, . . . 303 (1d)

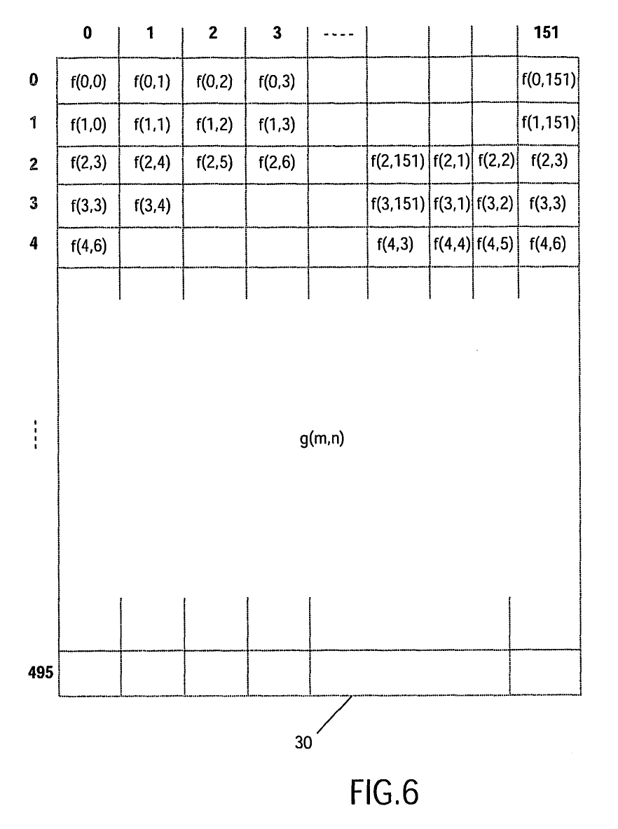

In a next step, a row shift operation is performed on the elements f(k,l) of the 152×496 matrix 20 so as to obtain a 152×496 third matrix 30 of which the elements will be indicated as g(m,n), as illustrated in FIG. 6. Rows 0 and 1 remain in place, the elements f(2,1=0-151) and f(3,1=0-151) of rows 2 and 3 are shifted 3 places to the left (i.e. to location g(m,n) with m=k and n=1-3), the elements f(4,1=0-151) and f(5,1=0-151) of rows 4 and 5 are shifted 6 places to the left (i.e. to location g(m,n) with m=k and n=1-6), etc. In general, for index i=0-247, the elements f(2i,l=0-151) and f(2i+1,1=0-151) of rows 2i and 2i+1 are shifted to locations g(m=k,n=1-3(i-1)). These shift operations are cyclic, which means that elements disappearing on the left are appended on the right. This can be expressed by the formula n=MOD(1-3(i-1),152).

Thus, the elements in a certain row stay within this row, i.e. m=k for all elements.

The purpose of this row shift operation is to prevent bit slip, i.e. to have all code words benefit from synchronization patterns written to disk, as will be clear to those skilled in the art.

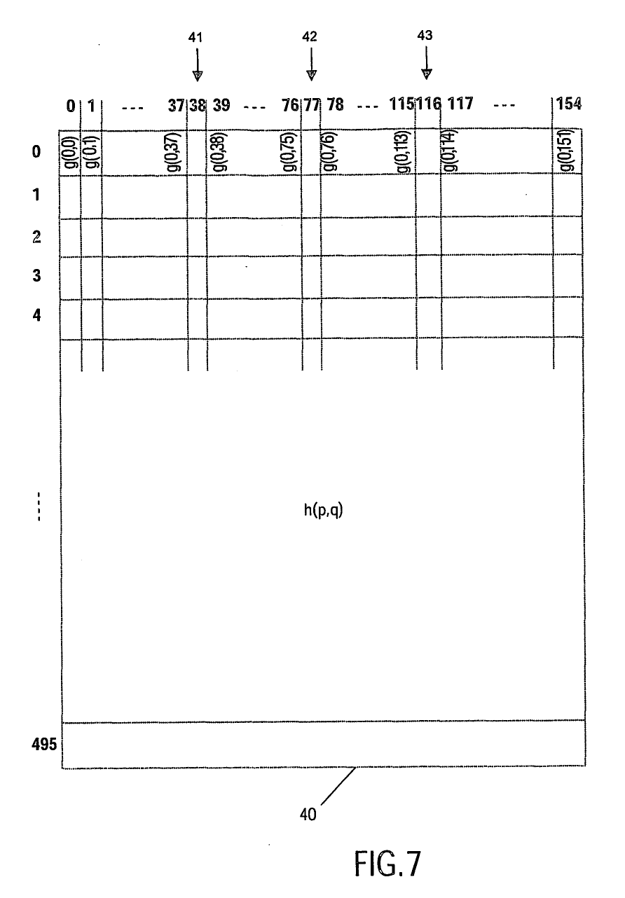

In a next step, three BIS columns 41, each having 496 bytes, are introduced into the third matrix 30 so as to obtain a 155×496 fourth matrix 40 of which the elements will be indicated as h(p,q), as illustrated in FIG. 7.

The BIS-columns 41 are inserted at regular intervals, i.e. between columns 37 and 38, between columns 75 and 76, and between columns 113 and 114 of the third matrix 30. Each BIS column contains 8 code words of 62 bytes each. Each code word consists of 30 data bytes and 32 parity bytes, so that the code words are very well protected against errors (better than the main data).

The BIS-columns 41 serve as a burst indicator (BIS=Burst Indicator Subcode). On decoding, the BIS-columns are decoded first. If two or more subsequent BIS symbols on the disc require correction, this is an indication for a burst error. This information is used to apply erasures during the correction of the main data code words, thus increasing the number of errors that can be corrected.

As was noted above, the BIS columns contain 24 code words of 62 bytes each. Like the main data, these code words are divided into segments, each segment containing one symbol of each code word. In a sixth step, a cyclic row shift is applied to the elements of the BIS columns, similarly as described above with respect to the fourth step, in order to protect all BIS-code words equally against bit slip.

As was noted above, the BIS code words consist of 30 data bytes and 32 parity bytes. The 30 data bytes provide storage space for information. In other words, the BIS columns form an auxiliary data channel in parallel to the main data channel. Part of this auxiliary data channel is used to store addressing information. The ECC block is divided into 16 groups, called sectors, of 31 rows each. Each sector contains one address, which is stored in the BIS-columns of the first three rows (giving 9 symbols to store the addressing information)

If the BIS code words were divided straightforwardly into segments, as in the main data channel, all parity symbols would end up in the BIS-columns of the last 256 rows of the ECC block. This would leave no room to store the addresses in the sectors contained in these rows. Instead, the symbols of the code words are divided into the segments such that the first 6 rows of the initial 24×62 matrix end up in the first 3 rows of each sector. The parity symbols end up in the last 16 rows of each sector. In other words, the symbols of the BIS code words are still divided into segments, but this is done in such a way that, for example, the first symbol of code word 1 may end up in the same segment as the fifth symbol of code word 10. This has no implications for the error correction capabilities since all symbols in a code word are of equal importance.

The address information may be regarded as a matrix of 16×9 (one address of 9 symbols for each of the 16 sectors in an ECC block). This matrix should be copied to the first 6 rows of the initial 24×62 BIS matrix in such a way that the addresses end up in the correct order in the first three rows of each sector after conversion of the 24×62 matrix to the 3×496 matrix. This is called address pre-interleaving.

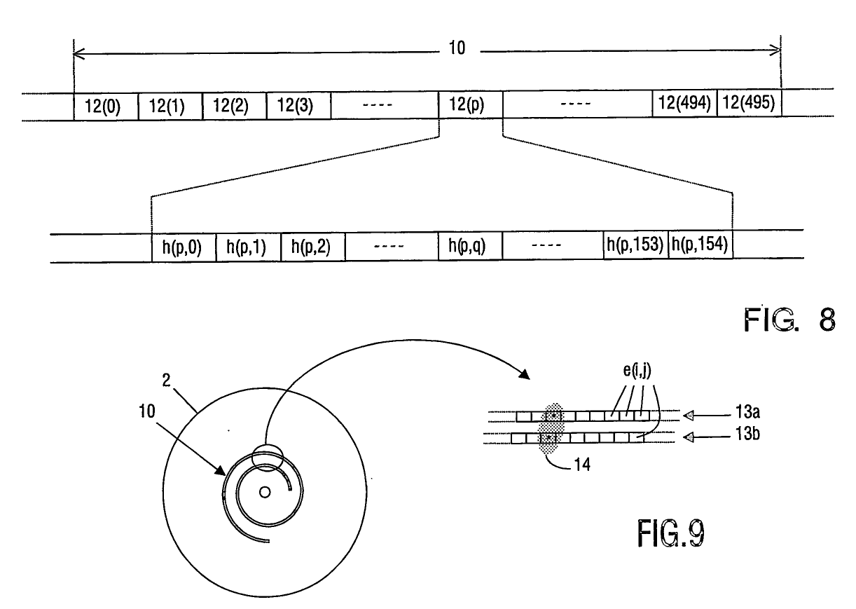

After the above-mentioned steps, the elements of the resulting matrix are written to disc row by row. In FIG. 8, a resulting track recording of an ECC block is visualized as a longitudinal ribbon. This recording comprises 496 block segments 12(p), each block segment 12(p) containing the 155 bytes of one row h(p,q=0-154). In other words, each code word 11(j) has one byte e(i,j) in each group of two consecutive block segments 12(p) and 12(p+1). Consequently, the spatial distance between two consecutive bytes e(i,j) and e(i+1,j) of one code word 11(j) is always as large as possible. It can also be seen that it is not possible to reconstruct all data bytes of all code words 11(j) until all block segments 12(p) of the ECC block have been read.

FIG. 9 schematically shows an SFFO disc 2 and a track recording of one 64-kByte ECC block close to the inner radius of the disc. As illustrated in the Figure, the length of this ECC block on disc corresponds to almost 2×360° track length, such that, over a substantial length, block segments in one track 13a and block segments in the neighboring track 13b belong to one and the same ECC block. In the enlargement of FIG. 9, a random error 14 is shown. This random error 14 has small dimensions, but still the size of the random error 14 is such as to affect three adjacent elements in track 13a and three adjacent elements in track 13b. The three affected adjacent elements in track 13a belong to three different code words; the same applies to the three affected adjacent elements in track 13b. However, it may happen that the block segments in neighboring tracks 13a and 13bare more or less aligned, such that one of the three affected adjacent elements in track 13a and one of the three affected adjacent elements in track 13bbelong to one and the same code word, as illustrated in FIG. 9 for the elements indicated with an asterisk. Thus, this one random error 14 will cause two errors in one code word. It will be clear that the same will apply to other elements, specifically to those elements immediately adjacent to the elements indicated with an asterisk.

The present invention proposes an algorithm for calculating a new order for writing the bytes of code words 11, such that the written information can be considered as constituting two ECC blocks of smaller size than the original ECC block 10. For explaining the general concept of this invention, the new order for writing the 75 392 bytes of 304 code words 11 will be described. The method of the present invention results in two 32-kByte ECC blocks, which also have the property of burst indication and address pre-interleaving as described in the above in respect of the state of the art.

Before explaining the present invention, an ECC block will be defined as a group of bytes which:

is written to disc as a closed group, i.e. the bytes are written consecutively to disc;

contains a collection of all (data and error correction) bytes of a certain number of code words, i.e. the collection contains all bytes of these code words and does not contain any byte of other code words.

Thus, for being able to decode one code word, it is necessary to read the entire group of 75 392 bytes, whereupon all 304 code words can be decoded. It is noted that an ECC block remains an ECC block, even if the order of the bytes is changed.

In the writing method of the state of the art, as described above, the 248 bytes of each code word are distributed over substantially the entire group of 75 392 bytes of the first matrix 10, so that this group constitutes one ECC block of 64 kBytes. In the writing method proposed by the present invention, the 248 bytes of any one code word are distributed over either the first half of the group or the second half of the group. Then, for being able to decode one code word, it is sufficient to read the corresponding half of the group only, whereupon 152 code words can be decoded while the other 152 code words cannot be decoded. Thus, in accordance with the invention, each half of the group in itself fulfils the above definition of an ECC block, now a block of 32 kBytes. In the following, these half groups will be indicated as small ECC blocks, to make the distinction from the original 64-kByte ECC block.

The present invention will be explained by first assuming that, in a first phase (first and second steps), the processing circuit 4 has constructed 304 code words, using the same type of code (Reed Solomon) as the prior art, as described above and visualized by the 304×248 primary matrix 10 of FIG. 4.

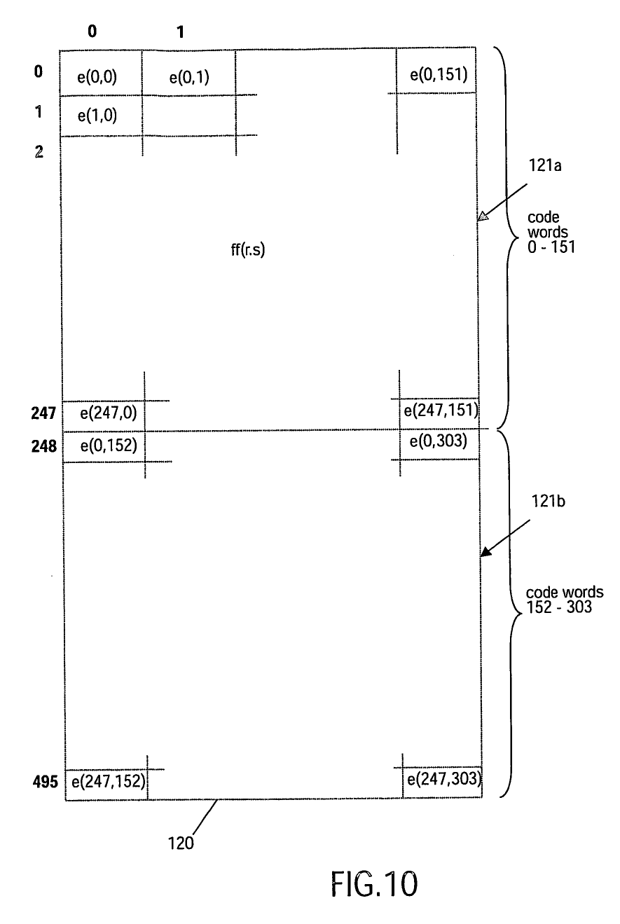

Next, a secondary matrix 120 having 152 columns of 496 bytes is constructed, each column comprising the bytes of two code words. This secondary 152×496 matrix 120 is illustrated in FIG. 10. The elements of this secondary matrix 120 will be indicated as ff(r,s).

In the method of the prior art, as described with reference to FIG. 5, a column of the secondary 152×496 matrix 20 is formed by “zipping” two code words into each other, i.e. alternatingly taking a byte from the one code word and a byte from the other code word. According to an important aspect of the present invention, a column of the secondary 152×496 matrix 120 is formed by placing two code words below each other. In principle, this may always be two code words adjacent to each other in the primary matrix 10. In the preferred embodiment illustrated in FIG. 10, code word (s+152) is placed below code word s, s ranging from 0 to 151. Thus, the elements e(i,j) of the original 304×248 ECC block matrix 10 are displaced to elements ff(r,s) of the 152×496 secondary matrix 120, according to the following relationships:
r=i for i=0-247 and j=0-151 (2a)
s=j for i=0-247 and j=0-151 (2b)
r=i+248 for i=0-247 and j=152-303 (2c)
s=j-152 for i=0-247 and j=152-303 (2d)

Thus, it can be seen that, for example, element e(0,152) is displaced to element ff(248,0).

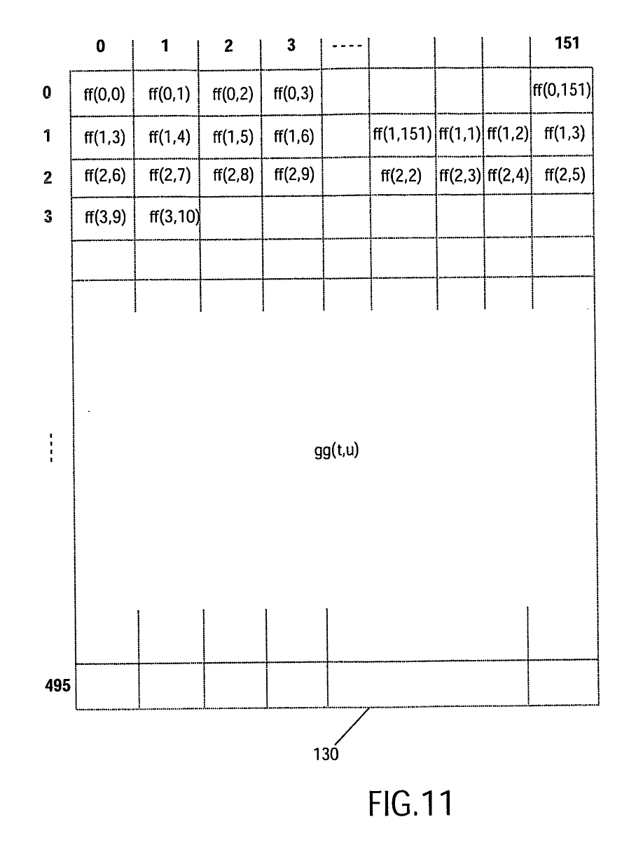

In a next step, a cyclic row shift operation is performed on the elements ff(r,s) of the 152×496 secondary matrix 120 so as to obtain a 152×496 third matrix 130 of which the elements will be indicated as gg(t,u), as illustrated in FIG. 11. Row 0 remains in place, the elements ff(1,s=0-151) of row 1 are shifted 3 places to the left (i.e. to location gg(1,u) with u=s-3), the elements ff(2,s=0-151) of row 2 are shifted 6 places to the left (i.e. to location gg(2,u) with u=s-6), etc. In general, for index r=0-495, the elements ff(r,s=0-151) of row r are shifted to locations gg((t,u) of the 152×496 third matrix 130, according to the following relationships:
t=r (3a)
u=MOD(1-MOD(3*MOD(m,248),152)+152,152) (3b)

It is noted that all elements in a certain matrix row stay within this row, i.e. t=r for all elements.

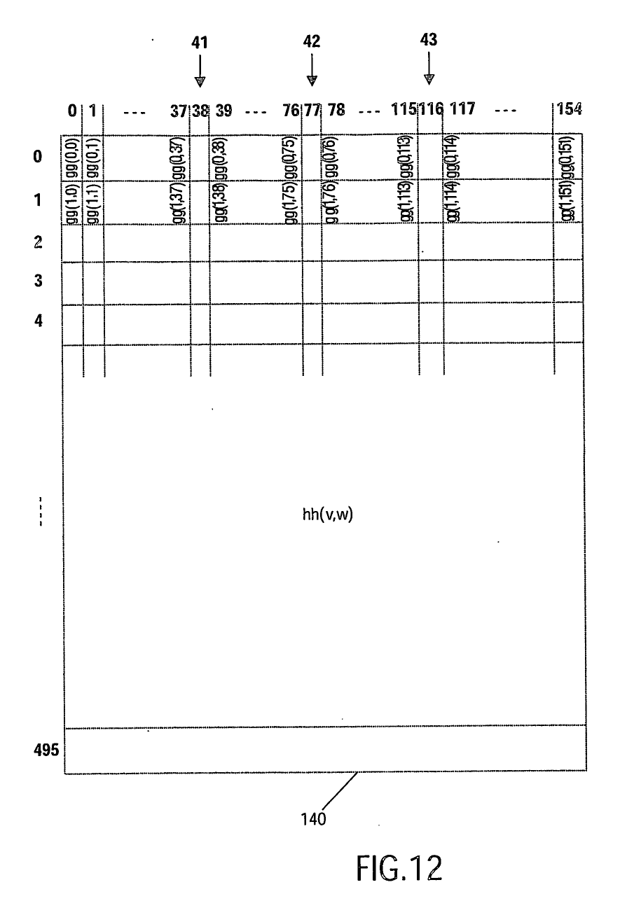

In a next step, three BIS columns 41, each having 496 bytes, are introduced into the third matrix 130 so as to obtain a 155×496 fourth matrix 140 of which the elements will be indicated as hh(v,w), as illustrated in FIG. 12.

This operation is similar to the operation described with reference to the prior art.

As was noted above, the BIS columns may be regarded as a 24×62 matrix, and the address information may be regarded as a 16×9 matrix (one address of 9 symbols for each of the 16 sectors in an ECC block). In the prior art, the 16×9 address matrix is copied to the first 6 rows of the initial 24×62 BIS matrix in such a way that the addresses end up in the correct order in the first three rows of each sector after conversion of the 24×62 matrix to the 3×496 matrix. According to the present invention, the 24×62 BIS matrix is divided into two 12×62 BIS-matrices. The addresses of the first 8 sectors are pre-interleaved into the first 6 rows of the first 12×62 BIS matrix. The addresses of the last 8 sectors are pre-interleaved into the first 6 rows of the second 12×62 BIS matrix. Then, the two 12×62 BIS matrices are each interleaved into a separate 3×248 matrix so as to form the BIS columns in a way similar to the way as described above for the larger BIS matrices. The first 3×248 matrix is inserted into the first small ECC block, the second 3×248 matrix is inserted into the second small ECC block.

All in all, when the bytes of the 24×62 BIS matrix are indicated as b_{BIS}(N,C), wherein C indicates the BIS code words (C=0-23), and wherein N indicates the symbols in the code words (N=0-61), these bytes are placed in unit uu, row rr and column cc in accordance with the following formulas:
uu=MOD({DIV(N,2)+4−DIV(MOD(C,12),3)},4)+4*MOD(N,2)+8*DIV(C,12) (4a)
rr=DIV(N,2) (4b)
cc=MOD({C+30−DIV(N,2)},3) (4c)

Furthermore, when the bytes of the 16×9 address matrix are indicated as AF(x,y), wherein y indicates the address words (y=0-15), and wherein x indicates the symbols in the address words (x=0-8), these bytes are placed in row rrr and column ccc in accordance with the following formulas:
rrr=2*DIV(x,3)+DIV({MOD(y,8)},4) (5a)
ccc=3*MOD({DIV(x,3)+16−y},4)+MOD({x+DIV(x,3)},3)+12*DIV(y,8) (5b)

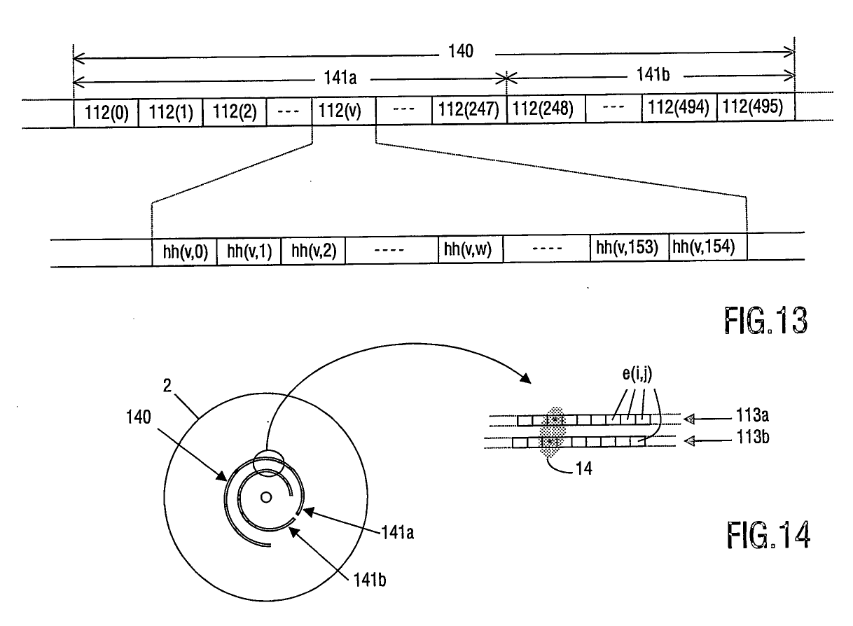

The row shift operation illustrated in FIG. 11 does not displace a matrix element ff(r,s) from one row to another. The same applies to the insertion of BIS columns as illustrated in FIG. 12. The same applies also to the interleaving operation of the BIS matrix and the address matrix, but these operations are not illustrated. Thus, it is possible to reconstruct all data bytes of the first 152 code words as soon as the first 248 block segments 112 have been read. Similarly, it is possible to reconstruct all data bytes of the second 152 code words as soon as the second 248 block segments 112 have been read. Therefore, since the primary matrix, in accordance with the present invention, has been defmed by placing two code words below each other, the upper half of matrix 120 may be considered as a small ECC block 121a containing the code words 0 to 151, and the lower half of matrix 120 may be considered as a small ECC block 121b containing the code words 152 to 303. Now if the elements hh(v,w) of this matrix 140 are written by first writing the elements hh(0,0), hh(0,1), hh(0,2), . . . hh(0,154) of the first row, then writing the elements hh(1,w=0-154) of the second row, then writing the elements hh(2,w=0-154) of the third row, etc, the resulting recording is visualized in FIG. 13, where the recording is shown as a longitudinal ribbon, comparable to FIG. 8. A collection of 155 elements hh(v,w=0-154) will be indicated as block segment 112(v). The recording comprises 496 of such block segments 112, each block segment 112 containing one byte of 152 of the code words 11. Consequently, the spatial distance between two bytes hh(v,w) and hh(v+1,w) of one code word has decreased by a factor two.

FIG. 14 is a drawing similar to FIG. 9, now illustrating the recording of matrix 140, and also illustrating the effect of a random error 14 on the recording of matrix 140. When comparing FIG. 14 with FIG. 9, it can be seen that the total length of recording 140 is equal to the total length of recording 10. However, the length of the recording of a small ECC block 141a, 141b (corresponding to small ECC blocks 121a, 121b, respectively, after row shift and introduction of BIS columns) is now shorter than the track length. If a random error 14 now affects two bytes in two adjacent tracks 113a, 113b, these two bytes will belong to different small ECC blocks 141a, 141b and, hence, will belong to different code words. Thus, the same random error 14 now only results in a maximum of one error in any code word.

It is noted that, as compared with the state of the art, the size of the ECC blocks has been reduced. Normally, a reduction of ECC block size results in a reduction of the effective correction capacity for burst errors. This is also true in the case of the present invention, when the effective error correction capacity of the method proposed by the invention for an SFFO disc is compared with the prior art method applied to a BRD disc. However, when the prior art method is applied to an SFFO disc, the effective error correction capacity is already reduced due to the fact that one ECC block occupies about two tracks. Taking this situation as a starting point, the reduction of ECC block size as proposed by the invention does not result in any further reduction in the effective correction capacity.

In the above, the present invention has been explained on the basis of 304 code words, in order to facilitate a comparison with the state of the art, which is also based on 304 code words. However, as explained, the matrix 120 may also be considered as a combination of two small ECC blocks, embodied by rows 0 to 247 and rows 248 to 495, respectively. Therefore, it is not necessary to manipulate 304 code words, but it is possible to manipulate just 152 code words. In other words, according to the present invention it is possible to define an ECC block 121a and implement the inventive concept of the present invention as soon as 152 code words have been received. This may reduce the required amount of memory space.

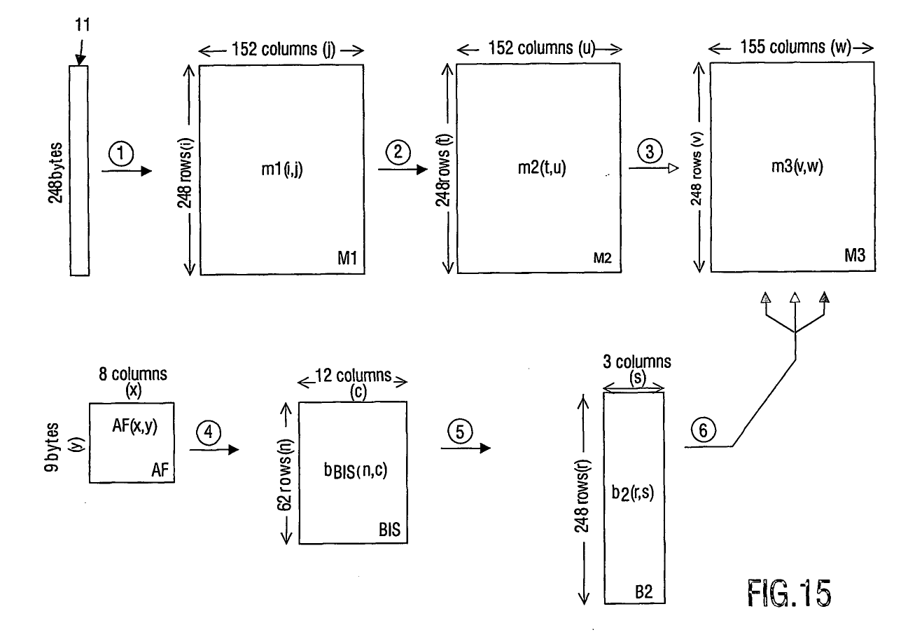

FIG. 15 illustrates schematically how a byte writing order in accordance with the present invention can be determined.

First, Nd data bytes are collected, and a code word 11 containing 248 bytes is defined by calculating Ne=248 -Nd error correction bytes, as described above.

In a next step (1), 152 of such code words are placed in a primary matrix M1 having 152 columns and 248 rows, elements of this primary matrix M1 being indicated as m1(i,j). Thus, byte i of code word j is placed at location m1(i,j).

In a next step (2), a cyclic row shift is performed, yielding a second matrix M2 having 152 columns and 248 rows, elements of this second matrix M2 being indicated as m2(t,u). Thus, element m1(i,j) of the first matrix M1 is placed at location m2(t,u) according to formulas:
t=i
u=MOD(j-MOD(3*i,152)+152,152)

In a next step (3), this second matrix M2 is transformed into a third matrix M3 having 155 columns and 248 rows, elements of this second third matrix M3 being indicated as m3(v,w), in order to create space for BIS columns. The transformation is such that element m2(t,u) of the second matrix M2 is placed at location m3(v,w) according to formulas:
v=t
w=u+DIV(u,38)

The steps (4), (5), and (6) illustrate the definition and insertion of BIS columns.

First, 8 addresses are defined, each having 9 bytes, and these 8 addresses are placed in an address matrix AF having 8 columns and 9 rows, elements of this address matrix AF being indicated as AF(x,y). Thus, byte y of address x is placed at location AF(x,y).

Also, 12 BIS code words are defined, each having 62 bytes, and these 12 BIS code words are placed in a BIS matrix BIS having 12 columns and 62 rows, elements of this BIS matrix being indicated as b_{BIS}(n,c).

Then a step (4) of address pre-interleaving is performed, wherein address bytes AF(x,y) are placed in the BIS matrix at locations b_{BIS}(n,c) according to formulas:
n=2*DIV(x,3)+DIV(y,4)
c=3*MOD({DIV(x,3)+8−y},4)+MOD({x+DIV(x,3)},3)

Then, in a step (5), the 12×62 BIS matrix BIS is transformed into a second BIS matrix B2 having 3 columns and 248 rows, elements of this second BIS matrix B2 being indicated as b₂(r,s), wherein BIS bytes bBIs(n,c) are placed in the second BIS matrix B2 at locations b₂(r,s) according to formulas:

uu=MOD({DIV(n,2)+4−DIV(c,3)},4)+4*MOD(n,2)
rr=DIV(n,2)
r=31*uu+rr
s=MOD({c+30−DIV(n,2)},3)

Hereinafter, each column of this second BIS matrix B2 will also be indicated as a BIS line BL(s) comprising 248 BIS bytes.

Then, in a step (6), the 3 columns of this second BIS matrix B2 are inserted into the third matrix M3, wherein B2 bytes b₂(r,s) are placed in the third matrix M3 at location m3(v,w) according to formulas:
w=39*s+38
v=r

It is noted that address bytes AF(x,y) are placed in the third matrix M3 at location m3(v,w) according to formulas:
w=39*MOD(y,3)+38
v=31*x+DIV(y,3)

Then the 38440 elements of this third matrix M3 are written in a row-by-row fashion. This can be expressed by the following formula
B(x)=m3(DIV(x,155),MOD(x,155)), wherein:
B(x) indicates the x-th byte to be written, x being an index ranging from 0 to 38439. Thus, B(0)=m3(0,0),B(1)=m3(0,1),B(2)=m3(0,2), . . . B(155)=m3(1,0), . . . B(38439)=m3(247,154).

It is noted that the re-ordering steps which are described above as a number of subsequent matrix transformations actually need not be performed as subsequent transformation steps. It should be clear that the overall re-ordering process can be considered as one matrix trrmsformation from an input 152×248 matrix M1 to an output 155×248 matrix M3, characterized by a unique transformation relation between the coordinates (i,j) of input matrix elements ml (i,j) and the coordinates (v,w) of output matrix elements m3(v,w). In other words, the coordinates (v,w) of output matrix elements m3(v,w) can be expressed as functions v(i,j) and w(i,j), which functions can be stored in a memory 8 of processing circuit 4, for example as lookup tables. Similarly, a unique transformation relation exists between the coordinates b_{BIS}(n,c) of the BIS matrix BIS and the coordinates (v,w) of output matrix elements m3(v,w).

Furthermore, it is of course possible that the processing circuit 4 actually constructs an output 155×248 matrix M3 having output matrix elements m3(v,w) and stores this matrix in an associated memory, and that the processor circuit 4 during a writing phase reads the elements, row by row, from this output 155×248 matrix M3. In fact, this is one possible, practical implementation. However, this is not necessarily the only possible implementation. The only important aspect is that the processing circuit 4 collects 152×Nd data bytes, calculates 152×Ne error correction bytes, calculates 12×62 BIS bytes, and transfers the collection of 38 440 bytes to the writing means 5 in the correct, predetermined order. In other words, the processing circuit 4 may be programmed in any way ensuring that it knows whether output byte ξ, ξ=0-38439, is one of the Nd data bytes, one of the error correction bytes, or one of the BIS bytes, and furthermore knows which one of said bytes.

The disc drive device 1 can also read data from disc 2. In a reading phase, the reading/writing means 5 read bytes from the disc 2, and provide the bytes thus read to the processing circuit 4, which may store the bytes in a 155×248 matrix M3. Then, in a reconstruction phase, the processing circuit 4 may reconstruct a 152×248 ECC block having elements e(i,j), using the same formulas as mentioned above. More particularly, for each value of index i and j, the process circuit 4 reads the corresponding byte at location m3(v,w) as defined by the above-mentioned formulas. If necessary, the process circuit 4 corrects possible errors for each code word 11 of this small ECC block formed by matrix M1 with elements e(i,j), using the error correction bytes. Now the processing circuit 4 can output the data bytes 7 at its output 9.

It should be clear to those skilled in the art that the present invention is not limited to the exemplary embodiments discussed above, but that various variations and modifications are possible within the protective scope of the invention as defined in the appended claims.

For example, although the present invention has been described against the background of the BRD standard, and the present invention is explained in the above for this specific example, the inventive concept of the present invention is also applicable if other standards are used as a starting point. Minor modifications may be necessary to adapt the exemplary method as described above to such a different standard, as will be clear to those skilled in the art.

Furthermore, although the present invention has been devised with a view to solving problems associated with circular record media, the information-writing method proposed by the invention may also be applied when writing information to linear media.

In the claims:

1. Method of writing information to a record medium, wherein 152 code words [11(j)] each having 248 bytes [m1(i,j)] and 12 BIS words each having 62 BIS bytes [b₂(r,s)] are combined so as to form an ECC block (M3) having 38440 elements [m3(v,w)], which elements are consecutively written to said medium.

2. Method of writing information to a record medium, comprising the following steps:
(a) calculating a predetermined number (Ne) of error correction bytes (Be) on the basis of a predetermined number (Nd) of data bytes (Bd) so as to form a code word (11) of 248 code word bytes;
(b) repeating step (a) until 152 of said code words [11(j)]have been formed, each comprising 248 code word bytes [m1(i,j)], j representing an index ranging from 0 to 151, i representing an index ranging from 0 to 247;
(c) generating 3 BIS lines [BL(s)] each comprising 248 BIS bytes [b₂(r,s)], s representing an index ranging from 0 to 2, r representing an index ranging from 0 to 247;
(d) writing the combination of 152×248 code word bytes [m1(i,j)] and 3×248 BIS bytes [b₂(r,s)] in an order obtainable by:
(d1) placing the 152 code words [11(j)] as columns in a 152×248 first matrix (Ml) having first matrix elements [m1(i,j)];
(d2) performing a predefined cyclic row shift operation on this first matrix (M1) so as to obtain a 152×248 second matrix (M2) having second matrix elements [m2(t,u)];
(d3) placing the second matrix elements [m2(t,u)] of this second matrix (M2) at location [m3(v,w)] of a 155×248 third matrix (M3) in accordance with the following formulas:
v=t
w=u+DIV(u,38)
(d4) placing the BIS bytes [b₂(r,s)] at location [m3(v,w)] of said 155×248 third matrix (M3) in accordance with the following formulas:
v=r
w=39*s+38
(d5) writing the elements [m3(v,w)] of said 155×248 third matrix (M3) in a row-by-row fashion in accordance with the following formula:
B(ξ)=m3(DIV(ξ,155),MOD(ξ,155)), wherein
B(ξ) indicates the ξ-th byte to be written, ξ being an index ranging from 0 to 38 439.

3. Method according to claim 2, wherein said cyclic row shift is performed in accordance with the following formulas:
t=i
u=MOD(j-MOD(3*i,152)+152,152)

4. Method according to claim 2, further comprising the steps of:
generating 12 BIS code words, each having 62 BIS bytes [b_{BIS}(n,c)],
c representing an index ranging from 0 to 11,
n representing an index ranging from 0 to 61;
and generating said 3 BIS lines [BL(s)] by combining 4 of said BIS code words so as to form a BIS line.

5. Method according to claim 4, wherein a relationship between said BIS bytes [b₂(r,s)] of said 3 BIS lines [BL(s)] on the one hand and said BIS bytes [b_{BIS}(n,c)] of said 12 BIS code words on the other hand complies with the following formulas:
b₂(r,s)=b_{BIS}(n,c) , with:
s=MOD({c+30−DIV(n,2)},3) and r=31*uu+DIV(n,2), wherein
uu=MOD({DIV(n,2)+4−DIV(c,3)},4)+4*MOD(n,2)

6. Method according to claim 4, further comprising the steps of:
generating 8 address words each having 9 address bytes [AF(x,y)],
x representing an index ranging from 0 to 7,
y representing an index ranging from 0 to 8;
putting said address bytes [AF(x,y)] into said 12 BIS code words,
wherein a relationship between said address bytes [AF(x,y)] of said address words on the one hand and said BIS bytes [b_{BIS}(n,c)] of said 12 BIS code words on the other hand complies with the following formulas:
b_{BIS}(n,c)=AF(x,y) with:
n=2*DIV(x,3)+DIV(y,4)
c=3*MOD({DIV(x,3)+8−y},4)+MOD({x+DIV(x,3)},3)

7. Method of reading information from a record medium, wherein an ECC block (M3) having 38 440 elements [m3(v,w)] is read, from which 152 code words [11(j)] each having 248 bytes [ml(i,j)]and 12 BIS words each having 62 BIS bytes [b₂(r,s)] are reconstructed.

8. Method of reading information from a record medium, comprising the following steps:
(a) reading 38 440 consecutive bytes [B(ξ)], ξ representing an index ranging from 0 to 38439;
(b) reconstructing 152 code words [11(j)] from said read bytes [B(ξ)], each code word comprising 248 code word bytes [ml(i,j)], j representing an index ranging from 0 to 151, i representing an index ranging from 0 to 247; wherein a relationship between said code word bytes [ml(i,j)] on the one hand and said read bytes [B(ξ)] on the other hand complies with the following formulas:
m1(i,j)=B(ξ), with ξ =i*155+u+DIV(u,38) wherein u=MOD(j-MOD(3*i,152)+152,152)

9. Method according to claim 8, wherein, the 248 bytes are submitted to an error correction processing in each code word [11(j)] thus reconstructed;
and wherein a predetermined number (Nd) from among the corrected bytes are outputted as data bytes (Bd).

10. Method according to claim 8, further comprising the step of reconstructing 12 BIS words from said read bytes [B(ξ)], each BIS word comprising 62 BIS bytes [b_{BIS}(n,c)]; c representing an index ranging from 0 to 11, n representing an index ranging from 0 to 61; wherein a relationship between said BIS bytes [b_{BIS}(n,c)] on the one hand and said read bytes [B(ξ)] on the other hand complies with the following formulas:
b_{BIS}(n,c)=B(ξ), with ξ=r*155+39*s+38 wherein: s=MOD({c+30-DIV(n,2)},3)
r=31*uu+DIV(n,2) with uu=MOD({DIV(n,2)+4-DIV(c,3)},4)+4*MOD(n,2)

11. Method according to claim 10, further comprising the step of reconstructing 8 address words from said reconstructed BIS words, each address word comprising 9 address bytes [AF(x,y)]; x representing an index ranging from 0 to 7, y representing an index ranging from 0 to 8; wherein a relationship between said address bytes [AF(x,y)] on the one hand and said BIS bytes [b_{BIS}(n,c)] on the other hand complies with the following formulas:
AF(x,y)=b_{BIS}(n,c), with n=2*DIV(x,3)+DIV(y,4)
c=3*MOD({DIV(x,3)+8-y},4)+MOD({x+DIV(x,3)},3)

12. Information recording/reading apparatus (1) designed to write information to a record medium (2) in accordance with any of claims 1-6, or to read information from a record medium (2) in accordance with claim 7, respectively.

13. Record carrier (2) containing information written by a method in accordance with claim 1.
